(19) United States
(12) Patent Application Publication
(10) Pub. No.: US 2014/0264271 A1
(43) Pub. Date: Sep. 18, 2014

(54) FERROELECTRIC MEMORY DEVICE

(71) Applicant: NATIONAL APPLIED RESEARCH LABORATORIES, Taipei City (TW)

(72) Inventors: Jia-Min Shieh, Hsinchu (TW); Wen-Hsien Huang, Hsinchu (TW); Yu-Chung Lien, Taoyuan County (TW); Chang-Hong Shen, Hsinchu (TW); Fu-Ming Pan, Hsinchu (TW); Hao-Chung Kuo, Hsinchu (TW)

(73) Assignee: NATIONAL APPLIED RESEARCH LABORATORIES, Taipei City (TW)

(21) Appl. No.: 13/845,366

(22) Filed: Mar. 18, 2013

(51) Int. Cl. H01L 29/15; H01L 29/06

(52) U.S. Cl. CPC H01L 29/151; H01L 29/0665
USPC 257/14

(57) ABSTRACT

A ferroelectric memory device includes a memory layer, made of a silicon-based ferroelectric memory material. The silicon-based ferroelectric memory material includes a mesoporous silica film with nanopores and atomic polar structures on inner walls of the nanopores. The atomic polar structures are formed by asymmetrically bonding metal ions to silicon-oxygen atoms on the inner walls, and the silicon-based ferroelectric memory material includes semiconductor quantum dots, metal quantum dots and metal-semiconductor alloy quantum dots.

### FIELD OF THE INVENTION

The present invention relates to a ferroelectric memory device, and particularly to a ferroelectric memory device using a silicon-based ferroelectric memory material compatible with a semiconductor manufacturing process.

### BACKGROUND OF THE INVENTION

A non-volatile memory (also referred as NVM) is a memory that can retain the stored data even when it is not powered. The characteristic of storing data without power by the non-volatile memory is similar to that of the typical hard disc. However, the write/read speed of the non-volatile memory is slower than the volatile memory such as a dynamic random-access memory (DRAM).

Nowadays, a floating-gate flash memory is one of the most commonly used non-volatile memory devices. Since the flash memory with a polysilicon floating gate has a slow write/erase speed and the storage capability thereof is limited, the researchers continuously make efforts in development of the novel non-volatile memory.

For further minimizing the device size, a quantum dot memory device has been disclosed. In the quantum dot memory device, the quantum dots existing in a thin film is used as the floating gate to storing charges in order to replace the conventional polysilicon floating gate. In views of the low operating voltage and the reliability, the quantum dot memory device is advantageous over the flash memory with the polysilicon floating gate. In addition, the tunneling oxide layer degradation of the quantum dot memory device from repeat writing and erasing procedures is much less serious than the flash memory with the polysilicon floating gate. Since the deep energy level (e.g. about 2˜3 eV) of the quantum dots belongs to a separate trap, the stored charges do not interfere with each other. Under this circumstance, even if the tunneling oxide layer has local defects, the charges are not completely lost. In addition, if the external power is turned off, the charges stored in the deep energy level are not lost.

However, during the process of manufacturing the quantum dot memory device, it is very difficult to control formation of the quantum dots. If the number of the quantum dots is inadequate or the distribution of the quantum dots is too decentralized, the quantum dot memory device fails to store sufficient charges. Under this circumstance, the applications of the quantum dots in the fabrication of the scaled-down memory device will be limited. On the other hand, if the nanocrystal is too large (e.g. larger than 10 nm) or closely packed, electrons may easily jump to the neighboring nanocrystals or penetrate through the defects of the underlying oxide layer. Under this circumstance, a current leakage problem occurs. Generally, bad quality of the oxide layers or various dielectric layers may result in different defect (capture) states, and thus the performance of the carrier mobility of the memory device are adversely affected. Under this circumstance, the operating speed and the reliability of the memory device are both deteriorated. In other words, the memory layer with a high-quality atomic polar structure and the defect passivation efficacy are important factors influencing miniaturization and stability of the device.

### SUMMARY OF THE INVENTION

An object of the present invention provides a metal ion-containing silicon-based ferroelectric memory material with enhanced interfacial switchable polarization. This silicon-based ferroelectric memory material is highly compatible with a semiconductor manufacturing process (e.g. a CMOS manufacturing process). This silicon-based ferroelectric memory material comprises quantum dots and atomic polar structures with ferroelectric properties. Generally, nanostructures of Si quantum dots composed of silicon and oxygen can be used for charge storage. Moreover, a low-temperature metal ion doping process and a pulse inductive coupled plasma chemical vapor deposition process are performed to effectively induce formation of the novel metal-silicon alloy quantum dots and atomic polar structure (APS). This nano scale composite material exhibits a strong photoluminescence (PL) effect in a visible spectrum. The strong photoluminescence (PL) effect indicates that the metal ions can enhance the interfacial switchable polarization between the alloy quantum dots and the mesoporous silica and between the metal and the mesoporous silica. In addition, the thickness of this composite material may be reduce to 20˜30 nm. It is demonstrated that the write/erase speed of the non-volatile memory is increased (shorter than 1 microsecond) and the charge storage time is prolonged. Consequently, the silicon-based ferroelectric memory material with the atomic polar structure can be applied to high-performance non-volatile memory devices in the future.

According to an aspect of the present invention, a ferroelectric memory device including a memory layer is provided. The memory layer is made of a silicon-based ferroelectric memory material including a mesoporous silica film with nanopores and atomic polar structures formed on inner walls of the nanopores.

According to another aspect of the present invention, a ferroelectric memory device is provided. A memory layer of the ferroelectric memory device is made of a silicon-based ferroelectric memory material including an amorphous dielectric film and atomic polar structures formed within the amorphous dielectric film. The atomic polar structures are formed by asymmetrically bonding metal ions to silicon-oxygen atoms.

According to a further aspect of the present invention, a ferroelectric memory device is provided. The ferroelectric memory device includes a silicon substrate, a first buffer layer formed on the silicon substrate, a memory layer formed on the first buffer layer, and a second buffer layer formed on the memory layer. The memory layer is made of a silicon-based ferroelectric memory material including a mesoporous silica film with nanopores and atomic polar structures formed on inner walls of the nanopores.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A˜1D schematically illustrate a method of fabricating a silicon-based ferroelectric memory material according to an embodiment of the present invention;

FIG. 2 is a Fourier transfer infrared spectrometer (FTIR) diagram of the mesoporous silica film containing the mixed alloy quantum dots and the atomic polar structure according to an embodiment of the present invention;

FIG. 3 is a photoluminescence (PL) spectrum diagram of the mesoporous silica film with nanopores according to an embodiment of the present invention;

FIG. 4A is a schematic cross-sectional view illustrating a metal-oxide-silicon structure of a non-volatile memory comprising a memory layer made of the silicon-based ferroelectric memory material according to the present invention;

FIG. 4B is a schematic cutaway perspective view illustrating the detailed structure of the metal-ion-doped mesoporous silica film as shown in FIG. 4A;

FIG. 5 is a capacitance-voltage analysis graph of the metal-oxide-silicon structure of FIG. 4A;

FIG. 6A is a schematic cross-sectional view illustrating a low temperature memory device according to an embodiment of the present invention;

FIG. 6B is a schematic cross-sectional view illustrating a low temperature memory device according to another embodiment of the present invention;

FIG. 6C is a schematic cross-sectional view illustrating the composite silica layer of the low temperature memory device as shown in FIG. 6A;

FIG. 7 is a transmission electron microscopy (TEM) image of a cross section of the mesoporous silica film of the memory device according to an embodiment of the present invention;

FIG. 8 is a voltage versus pulse width plot illustrating the write/erase speed of the low temperature memory device of FIG. 6A;

FIG. 9 is a voltage versus retention time plot illustrating the charge storage time of the low temperature memory device of FIG. 6A;

FIG. 10 is a voltage versus pulse width plot illustrating the write/erase speed of the low temperature memory device of FIG. 6B; and

FIG. 11 is a voltage versus retention time plot illustrating the charge storage time of the low temperature memory device of FIG. 6B.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

Due to the characteristics of low dielectric constant (low-k) and low reflectivity, porous silica materials can be widely used to form dielectric layers of integrated circuit devices, anti-reflection layers of solar cells, or the like. Since the porous materials have nanopores in periodical arrangement, researches pay much attention to the uses of the nanopores. Recently, in many patents and literatures, some methods of embedding quantum dots into the nanopores have been disclosed and applied to a variety of functional devices such as photo detectors or non-volatile memory devices.

For example, a method of fabricating a silicon-based ferroelectric memory material with nanopores is disclosed in Taiwanese Patent No. 1307162, which is filed by the same assignee of the present application. Firstly, a silica template with 2˜5 nm nanopores is provided by organic synthesis. Then, a pulsed high-density plasma assistant atomic layer chemical vapor deposition (pulsed high-density PAALD) process is performed. By the high-density PAALD process, silane plasma and hydrogen plasma are reacted to form quantum dots on the inner walls of the nanopores of the template. The density of the quantum dots is in the range between 1×10¹⁷˜1×10¹⁹ cm⁻³. It is found that this composite material has a clockwise hysteresis loop similar to the ferroelectric material.

For further improving the characteristics of the above silicon-based ferroelectric memory material, the present invention provides an improved method of fabricating the silicon-based ferroelectric memory material. In accordance with the present invention, a low-temperature mixing technology is used to dope metal europium ions into the nanopores of a mesoporous silica film. Consequently, a mesoporous silica film doped with metal europium ions is produced.

Hereinafter, a method of fabricating a silicon-based ferroelectric memory material according to an embodiment of the present invention will be illustrated with reference to FIGS. 1A˜1D.

Firstly, as shown in FIG. 1A, a precursor solution is prepared by adding an ethyl alcohol solution containing triblock copolymers 111 (such as Pluronic P-123, abbreviated as P123) to an acid-catalyzed silica sol-gel 112. For example, the acid-catalyzed silica sol-gel 112 is prepared by refluxing a mixture of tetraethyl orthosilicate (TEOS), water, HCl, and ethyl alcohol at 75° C. for 90 to 120 minutes, wherein the molar ratio of TEOS, P123, water, HCl, and ethyl alcohol in the mixture is 1:0.008˜0.3:3.5˜5.0:0.003:40, respectively. Then, a spin coating material 11 is prepared by adding europium nitrate hydrate (EuNO₃. 6H₂O) 113 to the precursor solution, wherein the (Eu/Si) molar ratio is 0.005˜003:1. Finally, the spin coating material 11 is coated on a substrate 1 by a spin coating process at a speed of 3,000 rpm for 30 seconds.

Then, as shown in FIG. 1B, the substrate 1 coated with the spin coating material 11 is subjected to a two-stage baking process. That is, the substrate 1 coated with the spin coating material 11 is baked at 50° C. for 30 minutes in the first stage and baked at 150° C. for 3 hours in the second stage. Consequently, a mesoporous silica film 12 doped with metal europium ions 1130 is obtained, wherein the diameter of the nanopores 120 of the mesoporous silica film 12 is controlled to be about 3 nm. As shown in the top right side of FIG. 1B, the metal europium ion 1130 is bonded onto the inner wall of the nanopore 120. As shown in the bottom right side of FIG. 1B, the metal europium ion 1130 is doped into the mesoporous silica film 12.

Then, as shown in FIG. 1C, a pulse inductive coupled plasma chemical vapor deposition (pulse ICPCVD) process is performed to mix and dissociate hydrogen plasma and silane plasma. Consequently, the mesoporous silica film 12 doped with the metal europium ions 1130 is subjected to interfacial modification. FIG. 1D schematically illustrates a cycle of pulse ICPCVD process. During the pulse ICPCVD process is performed, the hydrogen plasma is continuously provided, but the silane plasma is only provided for a time period T in the former stage. Consequently, mixed alloy quantum dots 13 (including silicon quantum dots, europium quantum dots and europium-silicon alloy quantum dots) are formed within the nanopore 120. In addition, the europium ion (Eu) and the asymmetric bonding silicon-oxygen atoms (Si—O) on the inner wall 121 of the nanopore 120 are asymmetrically bonded to each other in order to result in an atomic polar structure (APS) 14. The atomic polar structures 14 further include metal-oxygen bonding and the metal ions, i.e. europium ions. In this context, a mixed alloy quantum dot 13 and the atomic polar structure 14 are collaboratively indicated as Eu⁺³-APS. After measurement, it is found that Eu⁺³-APS has a clockwise hysteresis loop similar to or even superior to the ferroelectric material. In a case that an identical external electric field is applied, the Eu⁺³-APS has higher electric polarization intensity. Moreover, since the unit volume of the atomic polar structure (APS) 14 is much smaller than that of the silicon quantum dot 13, the atomic polar structure can be formed in a thinner device. In other words, the use of the atomic polar structure may facilitate miniaturization of device in the future.

FIG. 2 is a Fourier transfer infrared spectrometer (FTIR) diagram of the mesoporous silica film containing the mixed alloy quantum dots and the atomic polar structure according to an embodiment of the present invention. The lighter curve indicates the characteristics of europium ion-atomic polar structure (Eu⁺³-APS), and the darker curve indicates the characteristics of a quantum dot polar structure (QD-PS). It is demonstrated that the metal europium ion and Si—O can be effectively bonded to each other to form the special atomic polar structure.

FIG. 3 is a photoluminescence (PL) spectrum diagram of the mesoporous silica film with nanopores according to an embodiment of the present invention. The photoluminescence (PL) intensity is measured by using an excitation He—Cd laser (325 nm). It is demonstrated that a strong photoluminescence (PL) effect in a visible spectrum is generated. The strong photoluminescence (PL) effect indicates that the formation of the mixed alloy quantum dot 13 and the atomic polar structure 14 by introducing the metal ions may result in the characteristic changes of the interface between the metal ions and the mesoporous silica, under this circumstance, the intra-band electron transition. In FIG. 3, the waveband (590˜610 nm) of a specific intra-band transition of the europium ion is denoted as ⁵D₀→⁷F₂.

Since the interface between the metal ions and the mesoporous silica has superior interface polarization after the mesoporous silica film doped with the metal ions, this composite material may be served as a memory layer. Moreover especially, the thickness of the memory layer may be reduce to 20˜30 nm. The interface between the metal ions and the mesoporous silica of this memory layer will exhibit better interface polarization properties than the conventional ferroelectric material (domain >200 nm).

By the above fabricating method of the present invention, an ultra-thin metal-ion-doped mesoporous silica film can be produced. The ultra-thin metal-ion-doped mesoporous silica film may be integrated into a conventional metal-oxide-semiconductor (MOS) structure. It is noted that the metal ion used in the silicon-based ferroelectric memory material of the present invention is not limited to the europium ion (Eu⁺³). Alternatively, in some other embodiments, the metal ion is an inner transition metal ion such as erbium ion (Er⁺³), rhenium ion (La⁺³) or cerium ion (Ce⁺³). Alternatively, in some other embodiments, the metal ion is a transition metal ion such as a zinc ion (Zn⁺²), a platinum ion (Pt⁺²), a titanium ion (Ti⁺²) or a nickel ion (Ni⁺²). It is also noted that the mesoporous silica film can be extended to other suitable amorphous dielectric film with many nanopores and the atomic polar structures are formed within the amorphous dielectric film, particularly on the inner walls of the nanopores. The similar process is not repeated herein.

FIG. 4A is a schematic cross-sectional view illustrating a metal-oxide-silicon structure of a non-volatile memory comprising a memory layer made of the silicon-based ferroelectric memory material according to the present invention. The metal-oxide-silicon structure comprises a P-type silicon substrate 26, a first buffer layer 28, a metal-ion-doped mesoporous silica film 30, a second buffer layer 32, an upper electrode 34, and a lower electrode 36. The first buffer layer 28 is formed on the P-type silicon substrate 26. The metal-ion-doped mesoporous silica film 30 is formed on the first buffer layer 28. The second buffer layer 32 is formed on the metal-ion-doped mesoporous silica film 30. The upper electrode 34 is formed on the second buffer layer 32. The lower electrode 36 is formed under the P-type silicon substrate 26. Moreover, two electrical connection pads 38 and 40 are disposed on the upper electrode 34 and the lower electrode 36, respectively.

FIG. 4B is a schematic cutaway perspective view illustrating the detailed structure of the metal-ion-doped mesoporous silica film as shown in FIG. 4A. As shown in FIG. 4B, high-density mixed alloy quantum dots 42 (including silicon quantum dots, europium quantum dots and europium-silicon alloy quantum dots) are formed from bottom to top on the inner walls 44 of the nanopores of the mesoporous silica film 30. Moreover, since the europium ion (Eu⁺³) and the silicon-oxygen atoms (Si—O) on the inner walls 44 of the nanopores are asymmetrically bonded to each other, a plurality of Eu—Si—O atomic polar structures 43 are formed on the inner walls 44 of the nanopores. Since the unit volume of the atomic polar structure 43 is much smaller than that of the quantum dot 42, the atomic polar structure 43 can be formed in a thinner device. In other words, the use of the atomic polar structure may facilitate miniaturization of device in the future. Moreover, by effectively adjusting the Eu:Si atomic ratio to be in the range between 0.05:1 and 0.1:1, the fraction of the atomic polar structures 43 is higher than the fraction of the quantum dots 42. As such, the characteristics similar to the ferroelectric material will be enhanced.

FIG. 5 is a capacitance-voltage analysis graph of the metal-oxide-silicon structure of FIG. 4A. In comparison with the conventional quantum dot polar structure (denoted as QD-PS), the metal-ion-doped mesoporous silica film of the present invention (denoted as Eu⁺³-APS) exhibits a larger C-V memory window. The voltage shift is about 6V. In other words, this memory material containing the metal-ion-doped mesoporous silica film has enhanced interface polarization capability. Consequently, the silicon-based Eu⁺³-APS ferroelectric memory material is suitable for development of fast write/erase memory device.

For realizing the behaviors of the metal-ion-doped mesoporous silica film in a memory device, the present invention further provides a low temperature memory device. FIG. 6A is a schematic cross-sectional view illustrating a low temperature memory device according to an embodiment of the present invention. In this embodiment, the substrate 60 is a glass substrate. By an in-situ doping process with low heat budget (<400° C.), an n⁺ microcrystalline silicon (pc-Si) film 61, an intrinsic microcrystalline silicon film 62, a composite silica layer 63 and an aluminum electrode 64 are sequentially deposited on the glass substrate 60. The resulting structure of the low temperature memory device is shown in FIG. 6A.

FIG. 6B is a schematic cross-sectional view illustrating a low temperature memory device according to another embodiment of the present invention. The substrate 70 is a silicon-on-insulator substrate. Firstly, a composite silica layer 73 and a metal electrode layer 74 are sequentially deposited on the silicon-on-insulator substrate 70 to define a gate structure 79. Then, by using the gate structure 79 as an implantation mask, a source/drain region 71 is formed in the surface of the silicon-on-insulator substrate 70. The resulting structure of the low temperature memory device is shown in FIG. 6B. In this embodiment, the silicon-on-insulator substrate is produced by performing a laser crystallization process to convert an amorphous silicon substrate into a polycrystalline silicon substrate and then doping the polycrystalline silicon as a p-type substrate.

FIG. 6C is a schematic cross-sectional view illustrating the composite silica layer of the low temperature memory device as shown in FIG. 6A. As shown in FIG. 6C, the composite silica layer 63 comprises a tunneling oxide layer 630, a metal-ion-doped mesoporous silica film 631, and a capping oxide layer 632. The structures of the composite silica layer 73 are similar to those of the composite silica layer 63, and are not redundantly described herein.

FIG. 7 is a transmission electron microscopy (TEM) image of a cross section of the mesoporous silica film of the memory device according to an embodiment of the present invention. FIG. 7 shows a high density of quantum dots (1.2×10¹⁸ cm⁻²) in a periodic arrangement. The size of the quantum dots is about 2˜4 nm. These quantum dots with different lattice plane spacing indicate mixed alloy quantum dots in different crystal orientations. That is, these quantum dots include silicon quantum dots, europium quantum dots and europium-silicon alloy quantum dots.

FIG. 8 is a voltage versus pulse width plot illustrating the write/erase speed of the low temperature memory device of FIG. 6A. Under the operating voltage of +10V/−10V, the write/erase time is much shorter than 1 microsecond. In other words, the write/erase speed is very fast. FIG. 9 is a voltage versus retention time plot illustrating the charge storage time of the low temperature memory device of FIG. 6A. After the charge storage time is longer than 1,000 seconds, a large memory window is still retained. The magnitude of the memory window is about 1.8V (see FIG. 9). FIG. 10 is a voltage versus pulse width plot illustrating the write/erase speed of the low temperature memory device of FIG. 6B. In the operating voltage +10V/−10V, the write/erase time is about 100 nanoseconds. FIG. 11 is a voltage versus retention time plot illustrating the charge storage time of the low temperature memory device of FIG. 6B. After the charge storage time is longer than 1,000 seconds, a large memory window is still retained. The magnitude of the memory window is about 1.9V (see FIG. 11). In other words, a satisfied charge storage time is achieved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A ferroelectric memory device comprising a memory layer, which is made of a silicon-based ferroelectric memory material, comprising:
a mesoporous silica film with a plurality of nanopores; and
a plurality of atomic polar structures formed on inner walls of the nanopores.

2. The ferroelectric memory device according to claim 1, wherein the atomic polar structures are formed by asymmetric bonding, silicon-oxygen atoms (Si—O), on the inner walls of the nanopores.

3. The ferroelectric memory device according to claim 2, wherein the atomic polar structures are formed by asymmetrically bonding metal ions to the silicon-oxygen atoms on the inner walls of the nanopores.

4. The ferroelectric memory device according to claim 3, wherein the atomic polar structures further comprises metal-oxygen bonding and the metal ions.

5. The ferroelectric memory device according to claim 3, wherein the metal ions are europium ions (Eu⁺³), erbium ions (Er⁺³), rhenium ions (La⁺³), cerium ions (Ce⁺³), zinc ions (Zn⁺²), platinum ions (Pt⁺²), titanium ions (Ti⁺²) or nickel ions (Ni⁺²).

6. The ferroelectric memory device according to claim 1, wherein the silicon-based ferroelectric memory material further comprises a plurality of quantum dots, which are attached on the inner walls of the nanopores, the quantum dots including a plurality of semiconductor quantum dots, a plurality of metal quantum dots and a plurality of metal-semiconductor alloy quantum dots.

7. The ferroelectric memory device according to claim 6, wherein the semiconductor quantum dots are silicon quantum dots, the metal quantum dots are europium quantum dots, and the metal-semiconductor alloy quantum dots are europium-silicon alloy quantum dots.

8. A ferroelectric memory device comprising a memory layer, which is made of a silicon-based ferroelectric memory material comprising:
an amorphous dielectric film; and
a plurality of atomic polar structures formed within the amorphous dielectric film, wherein the atomic polar structures are formed by asymmetrically bonding metal ions to silicon-oxygen atoms.

9. The ferroelectric memory device according to claim 8, wherein the amorphous dielectric film further comprises a plurality of nanopores.

10. The ferroelectric memory device according to claim 9, wherein the plurality of atomic polar structures are formed on inner walls of the nanopores.

11. The ferroelectric memory device according to claim 10, wherein the silicon-based ferroelectric memory material further comprises a plurality of quantum dots, which are attached on the inner walls of the nanopores, the quantum dots including a plurality of semiconductor quantum dots, a plurality of metal quantum dots and a plurality of metal-semiconductor alloy quantum dots.

12. The ferroelectric memory device according to claim 11, wherein the semiconductor quantum dots are silicon quantum dots, the metal quantum dots are europium quantum dots, and the metal-semiconductor alloy quantum dots are europium-silicon alloy quantum dots.

13. The ferroelectric memory device according to claim 8, wherein the atomic polar structures further comprises metal-oxygen bonding and the metal ions.

14. The ferroelectric memory device according to claim 8, wherein the metal ions are europium ions (Eu⁺³), erbium ions (Er⁺³), rhenium ions (La⁺³), cerium ions (Ce⁺³), zinc ions (Zn⁺²), platinum ions (Pt⁺²), titanium ions (Ti⁺²) or nickel ions (Ni⁺²).

15. A ferroelectric memory device comprising a silicon substrate, a first buffer layer formed on the silicon substrate, a memory layer formed on the first buffer layer, and a second buffer layer formed on the memory layer, wherein the memory layer is made of a silicon-based ferroelectric memory material comprising:
a mesoporous silica film with a plurality of nanopores; and
a plurality of atomic polar structures formed on inner walls of the nanopores.

16. The ferroelectric memory device according to claim 15, wherein the atomic polar structures are formed by asymmetric bonding, silicon-oxygen atoms, on the inner walls of the nanopores.

17. The ferroelectric memory device according to claim 16, wherein the atomic polar structures are formed by asymmetrically bonding metal ions to the silicon-oxygen atoms on the inner walls of the nanopores.

18. The ferroelectric memory device according to claim 17, wherein the metal ions are europium ions (Eu⁺³), erbium ions (Er⁺³), rhenium ions (La⁺³), cerium ions (Ce⁺³), zinc ions (Zn⁺²), platinum ions (Pt⁺²), titanium ions (Ti⁺²) or nickel ions (Ni⁺²).

19. The ferroelectric memory device according to claim 15, wherein the silicon-based ferroelectric memory material further comprises a plurality of quantum dots formed on the inner walls of the nanopores, the quantum dots including a plurality of semiconductor quantum dots, a plurality of metal quantum dots and a plurality of metal-semiconductor alloy quantum dots.

20. The ferroelectric memory device according to claim 19, wherein the semiconductor quantum dots are silicon quantum dots, the metal quantum dots are europium quantum dots, and the metal-semiconductor alloy quantum dots are europium-silicon alloy quantum dots.
